(19) United States
(12) Patent Application Publication
(10) Pub. No.: US 2014/0091341 A1
(43) Pub. Date: Apr. 3, 2014

(54) DEVICE AND METHOD FOR AN LED WITH A CONVEX COVER

(71) Applicants: Cheih Oh Yang, (US); Wei Ou Yang, (US); JIANGSU SUN & MOON LIGHTING CO.,LTD., Yancheng city (CN)

(72) Inventors: CHIEH OU YANG, New Taipei City (TW); WEI OU YANG, Taipei City (TW)

(73) Assignee: JIANGSU SUN & MOON LIGHTING CO.,LTD., Yancheng city (CN)

(21) Appl. No.: 13/846,689

(22) Filed: Mar. 18, 2013

(30) Foreign Application Priority Data
Sep. 29, 2012 (CN) 201210372739.6
Sep. 29, 2012 (CN) 201220507354.1

(51) Int. Cl. H01L 33/08

(52) U.S. Cl. CPC H01L 33/08
USPC 257/89; 438/28

(57) ABSTRACT

An approach is provided for a device and a method for an LED with a convex cover, which comprises multiple LED diodes compartmentalized to at least one group. Each group of LED diodes forms an electrical loop on a PCB, and has at least one first LED diode on a center region and at least two second LED diodes on a periphery region. Each second LED diode is connected to the first LED diode in series, and connected to the other second LED diode in parallel. The power of the first LED diode is higher than the second LED diode.

### FIELD OF THE INVENTION

Embodiments of the present invention relate to an LED device, especially toward a device and a method for an LED with a convex cover such as a convex lens or a bulb.

### BACKGROUND

An LED device, in general, comprises an LED power module, a driver, a heat dissipating components, a PCB board and multiple LED diodes mounted on the PCB board. The LED power module is connected between the LED device and a line power source, which is configured for providing a desired direct current (DC) voltage to the LED device. The driver is connected to the LED power module and the PCB board that drives the LED diodes. The heat dissipating components are configured to dissipate the generated heat from LED diodes that ensures the LED diodes work properly.

The cover (i.e. lens or the bulb) is often used in an actual practice of the LED device, and the LED diodes used underneath the cover normally have the same power. Due to the characteristic of the cover which the light extraction rate is most efficiency at center area and radially decreases toward the side of the cover, especially for convex cover. Therefore, when using same power output LED diodes, there will have power waste at the side regions. Further, the price for each LED diode is according to the power of the LED diode. The price for a 10 Watts (W) LED diode can be 4 to 5 times higher than a 5 W LED diode. In other words, a person can buy five 5 W LED diodes instead of one 10 W LED diodes.

Therefore, there is a need to develop an LED light with provides better LED diodes configuration that is able to increase the power efficiency and decrease the manufacturing cost.

### SOME EXEMPLARY EMBODIMENTS

These and other needs are addressed by the present invention, wherein an approach is provided for a device and a method for an LED with a convex cover that is able to increase the power efficiency and decrease the manufacturing cost.

According to one aspect of an embodiment of the present invention, a device for an LED with a convex cover comprises multiple LED diodes compartmentalized to at least one group. Each group of LED diodes forms an electrical loop on a PCB, and has at least one first LED diode on a center region and at least two second LED diodes on a periphery region. Each second LED diode is connected to the first LED diode in series, and connected to the other second LED diode in parallel. The power of the first LED diode is higher than the second LED diode.

According to one aspect of an embodiment of the present invention, a method for an LED with a convex cover comprises acts of compartmentalizing multiple LED diodes to at least one first LED diodes and at least two second LED diode based on the output of the power sequentially, grouping at least one first LED diode and at least two second diodes into a group, and locating at least one first LED diode in a center region and at least two second diodes in a periphery region for each group. As for each group, at least two second LED diodes are connected in parallel and connect to the first LED diode in series. The connections of LED diodes in each group can be in series, parallel or serie-parallel.

### BRIEF DESCRIPTION OF THE DRAWINGS

The invention is illustrated by way of example, and not by way of limitation, in the figures of the accompanying drawings in which like reference numerals refer to similar elements and in which:

FIG. 1 is an exemplary diagram of an LED device illustrating a configuration of LED diodes in accordance with an embodiment of the present invention;

FIG. 2 is an exemplary diagram of an LED device illustrating a configuration of LED diodes in accordance with another embodiment of the present invention;

FIG. 3 is an exemplary diagram of an LED device illustrating a configuration of LED diodes in accordance with yet another embodiment of the present invention; and

FIGS. 4A and 4B are the flowchart of an method for an LED in accordance with an embodiment of the present invention.

### DESCRIPTION OF THE PREFERRED EMBODIMENT

A method and device of an LED with convex cover is disclosed. In the following description, for the purposes of explanation, numerous specific details are set forth in order to provide a thorough understanding of the present invention. It is apparent, however, to one skilled in the art that the invention may be practiced without specific details or with an equivalent arrangement. In other instances, well-known structures and devices are shown in block diagram form in order to avoid unnecessarily obscuring the embodiments of the present invention.

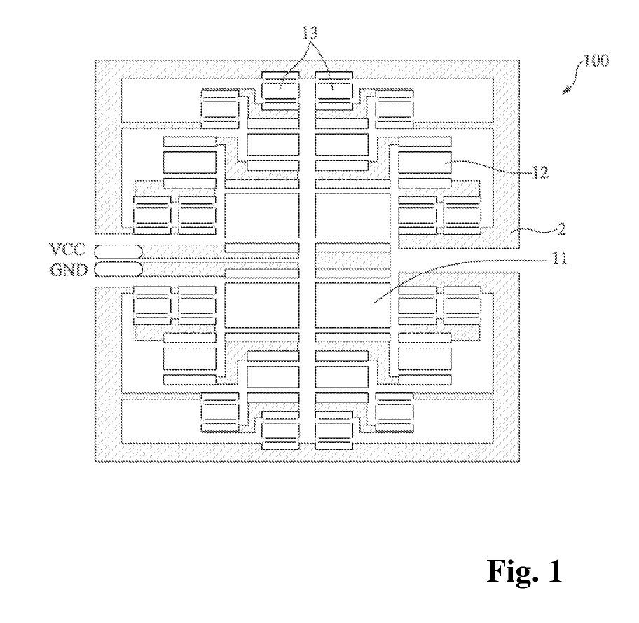

With reference to FIG. 1, FIG. 1 shows an LED arrangement of an LED device in accordance with the present invention. In one embodiment, the device for an LED with convex cover comprises multiple LED diodes compartmentalized to at least one group. Each group of LED diodes forms an electrical loop on a PCB 2, and has at least one first LED diode 11 on a center region and at least two second LED diodes 12 on a periphery region. Each second LED diode 12 is connected to the first LED diode 11 in series, and connected to the other second LED diode 12 in parallel. The power of the first LED diode 11 is higher than the second LED diode 12.

Further, as shown in FIG. 1, the group of the LED diodes may further comprise multiple third LED diodes 13 on the periphery region. Every two third LED diodes 13 is corresponded and connected to the second LED diode 12. The power of the third LED diode 13 is smaller than the power of the second LED diode 12. Therefore, the LED diodes and the first, second and third LED diodes 11, 12, 13 are formed in hierarchical nature of tree stricture.

In this embodiment, the LED device has an overall power output of 100 Watts (W). The LED diodes are compartmentalized into four groups. Each group has a first LED diode 11, two second LED diodes 12 and four third LED diodes 13. Each second LED diode 12 is corresponded to two third LED diodes 13. The four groups of the LED diodes are evenly distributed in a sector (i.e. fan-shaped) of a circle, and each sector has a central angle of 90° (i.e., quadrants). In this embodiment, each group of the LED diodes is connected to the other group of the LED diodes in series. However, a person skilled in the art will realize that the connections among diodes can be in series, parallel or serie-parallel.

Further, the above embodiment may further implement by replacing the LED diodes into a Red, a Green and a Blue (RGB) LED diodes to achieve multiple color appearance. However, the actual color mixing can be implemented by an external controller that controls the LED diodes. Such control technology is a known by a skilled person.

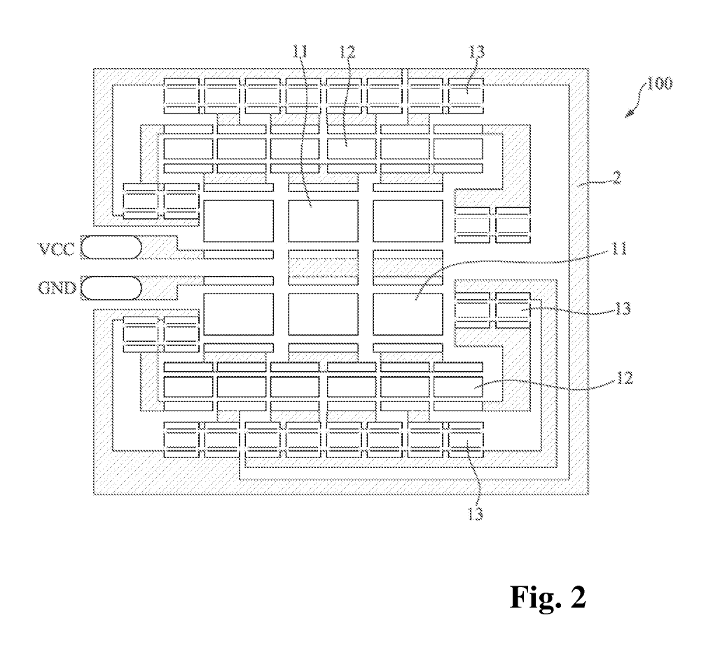

With reference to FIG. 2, another embodiment of a device for an LED with convex cover. In this embodiment, the LED device has an overall power output of 150 W. The LED diodes are compartmentalized into six groups. Similarly to the above mentioned embodiment, each group has a first LED diode 11, two second LED diodes 12 and four third LED diodes 13.

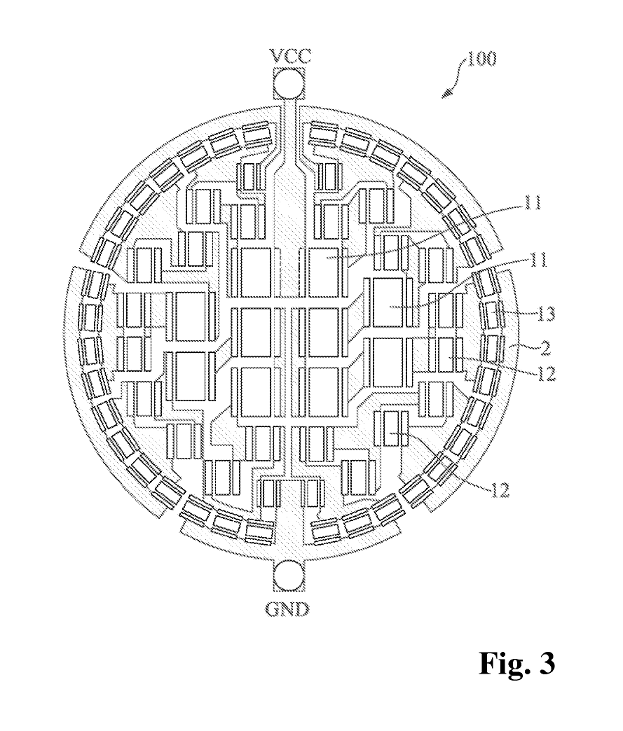

With reference to FIG. 3, yet another embodiment of a device for an LED with convex cover. In this embodiment, the LED device has an overall power output of 300 W. The LED diodes are compartmentalized into six groups. The different between above mentioned embodiment is to have multiple additional second LED diodes 12 and third LED diodes 13 mount on a auxiliary region to fill up with the empty space and some group has an additional first LED diode where the additional first LED diode is connected to the first LED diode in series.

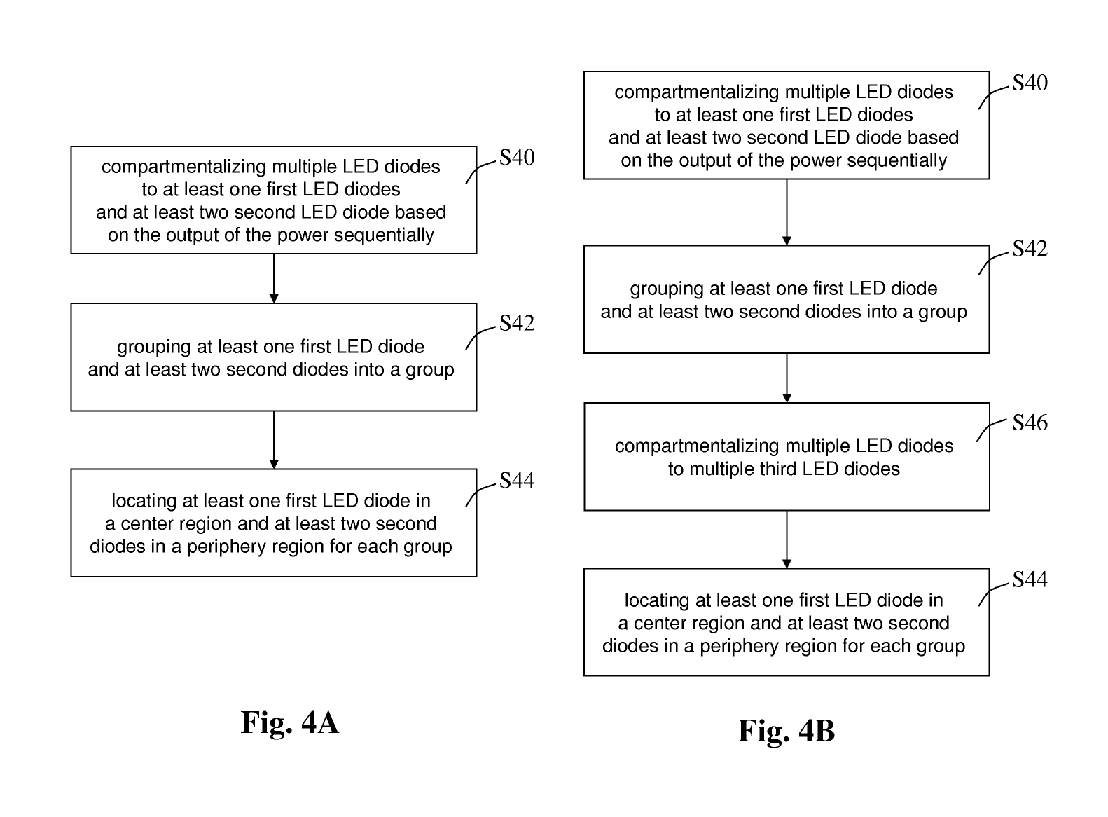

With reference to FIG. 4A, a method for an LED with convex cover comprises acts of S40 compartmentalizing multiple LED diodes to at least one first LED diodes and at least two second LED diode based on the output of the power sequentially, S42 grouping at least one first LED diode and at least two second diodes into a group, and S44 locating at least one first LED diode in a center region and at least two second diodes in a periphery region for each group. As for each group, at least two second LED diodes are connected in parallel and connect to the first LED diode in series. The connections of LED diodes in each group can be in series, parallel or serie-parallel.

With reference to FIG. 4B, the method further comprises act of S46 compartmentalizing multiple LED diodes to multiple third LED diodes, wherein the power of the third LED diode is smaller than the second LED diode, and at least every two third LED diodes are corresponded and connected to a second LED diodes. The at least two third LED diodes are connected in paralleled. The third LED diodes are located in the periphery region.

Accordingly, the device and a method for an LED with a convex cover divides multiple LED diodes into several groups and make each group to have different power output of LED diodes, whereby the highest power output LED diode (i.e., the first LED diode) is located in the center region for highest light output, and lower power output LED diode (i.e. the second or third LED diode) in the periphery region. Therefore, comparing to the conventional LED device, the embodiments of the present invention provides lower manufacturing cost and higher efficiency with remain same amount of light output and power consumption.

While the invention has been described in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

What is claimed is:

1. A device for an LED with a convex cover, comprising:
multiple LED diodes being compartmentalized to at least one group, each group of LED diodes forms an electrical loop on a PCB, and comprising
at least one first LED diode being located on a center region; and
at least two second LED diodes being on a periphery region, each second LED diode being connected to the first LED diode in series, and being connected to the other second LED diode in parallel, wherein the power of the first LED diode is higher than the second LED diode.

2. The device as claimed in claim 1, further comprising multiple third LED diodes located in the periphery region, and the every two third LED diodes being corresponded and connected to the second LED diode, wherein the power of the third LED diode is smaller than the power of the second LED diode.

3. The device as claimed in claim 2, wherein the second LED diode or the third LED diode comprises a red LED diode.

4. The device as claimed in claim 1, wherein the each group of the LED diodes is distributed in a circular sector.

5. The device as claimed in claim 1, wherein the multiple LED diodes comprise a red LED diode, a green LED diode and a blue LED diode that implements a color mixing control.

6. The device as claimed in claim 1, wherein the connections of the multiple LED diodes in each group are in series, parallel or serie-parallel.

7. A method for an LED with a convex cover, comprising:
compartmentalizing multiple LED diodes to at least one first LED diodes and at least two second LED diode based on the output of the power sequentially;
grouping at least one first LED diode and at least two second diodes into a group; and
locating at least one first LED diode in a center region and at least two second diodes in a periphery region for each group, wherein at least two second LED diodes are connected in parallel and connect to the first LED diode in series.

8. The method as claimed in claim 7, further comprising:
compartmentalizing multiple LED diodes to multiple third LED diodes, wherein the power of the third LED diode is smaller than the second LED diode, and at least every two third LED diodes are corresponded and connected to a second LED diodes.

9. The method as claimed in claim 7, wherein the multiple LED diodes comprise a red LED diode, a green LED diode and a blue LED diode that implements a color mixing control.

10. The method as claimed in claim 7, wherein the connections of the multiple LED diodes in each group are in series, parallel or serie-parallel.
